(19) United States
(12) Patent Application Publication
(10) Pub. No.: US 2021/0135145 A1
(43) Pub. Date: May 6, 2021

(54) COVER WINDOW STRUCTURE AND OLED DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Xia CHEN, Wuhan (CN)

(21) Appl. No.: 16/798,648

(22) Filed: Feb. 24, 2020

(30) Foreign Application Priority Data
Nov. 5, 2019 (CN) 201911072037.4

(51) Int. Cl. H01L 51/52; H01L 27/32; H01L 51/00

(52) U.S. Cl. CPC H01L 51/524; H01L 27/3244; H01L 2251/558; H01L 2251/5338; H01L 51/0097

(57) ABSTRACT

The present disclosure provides a cover window structure, including a transparent substrate and a hard coating layer disposed on the transparent substrate, wherein a region near a contact surface between the transparent substrate and the hard coating layer forms a molecular exchange layer by a molecular exchange method, and a hardness of the molecular exchange layer is greater than a hardness of the transparent substrate and is less than a hardness of the hard coating layer. The present disclosure further provides an organic light-emitting diode (OLED) display device which includes the cover window structure of the present disclosure, and by using this cover window structure design, bending resistance of the cover window structure is effectively improved.

### FIELD OF INVENTION

The present disclosure relates to the field of display technologies, and more particularly, to a cover window structure and an organic light-emitting diode (OLED) display device.

### BACKGROUND OF INVENTION

With introduction of new-generation high-performance electronic products, flexible and bendable consumer electronics have attracted investment and development from major manufacturers. In order to achieve dynamic bending of foldable organic light-emitting diode (OLED) products, it is necessary for new materials, new designs, and new manufacturing processes to be introduced to improve performances of flexible and bendable OLED products. Currently, OLED display devices include a display panel and a cover window structure disposed on one side of a display surface of the display panel to protect the display panel. However, when the cover window structure is made of a flexible material, its hardness is too low to effectively protect the display panel; and when the cover window structure is made of an excessively hard material, the cover window structure easily breaks during bending processes and cannot effectively protect the display panel, thereby affecting the performance of OLED displays.

In summary, in existing cover window structures and OLED display devices, the material adopted for the cover window structures are too soft or too hard, making it difficult to effectively protect the OLED display panel, which further affects the performance of the OLED display devices.

### SUMMARY OF INVENTION

The present disclosure provides a cover window structure and an organic light-emitting diode (OLED) display device effectively improving the hardness and bendability of the cover window structure, solving the existing cover window structure technical problems that the material of the cover window structure too soft or too hard, which cannot effectively protect the OLED display panel and the OLED display device, and further, affect the performance of the OLED display device.

To solve the above problems, the technical solutions provided by the present disclosure are as follows:

The present disclosure provides a cover window structure, including a transparent substrate and a hard coating layer disposed on the transparent substrate;
wherein a region near a contact surface between the transparent substrate and the hard coating layer forms a molecular exchange layer by a molecular exchange method, a hardness of the molecular exchange layer is greater than a hardness of the transparent substrate and is less than a hardness of the hard coating layer.

According to one preferred embodiment of the present disclosure, the molecular exchange method is a high-temperature heating method.

According to one preferred embodiment of the present disclosure, a heating temperature of the high-temperature heating method is a higher one of a glass transition temperature of a material of the transparent substrate and a glass transition temperature of a material of the hard coating layer

According to one preferred embodiment of the present disclosure, a heating temperature of the high-temperature heating method is between a glass transition temperature of a material of the transparent substrate and a glass transition temperature of a material of the hard coating layer.

According to one preferred embodiment of the present disclosure, the molecular exchange method further includes a coating process improvement method.

According to one preferred embodiment of the present disclosure, a material of the transparent substrate is selected from the group of a polyimide, a polyethylene terephthalate, a polyethylene naphthalate, and a polymethylmethacrylate.

According to one preferred embodiment of the present disclosure, a thickness of the transparent substrate ranges between 30 microns and 60 microns.

According to one preferred embodiment of the present disclosure, a thickness of the hard coating layer ranges between 10 microns and 30 microns.

The present disclosure further provides an organic light-emitting diode (OLED) display device, including an OLED display panel and a cover window structure disposed on the display panel; wherein the cover window structure includes a transparent substrate and a hard coating layer disposed on the transparent substrate, a region near a contact surface between the transparent substrate and the hard coating layer forms a molecular exchange layer by a molecular exchange method, and a hardness of the molecular exchange layer is greater than a hardness of the transparent substrate and is less than a hardness of the hard coating layer.

According to one preferred embodiment of the present disclosure, the molecular exchange method is a high-temperature heating method or a coating process improvement method.

The beneficial effect of the present disclosure is that the cover window structure and the OLED display device provided by the present disclosure design the cover window structure as a hard-medium-soft sandwich structure, effectively improving the bending resistance of the cover window structure, and further improving the performance of OLED display devices.

### DESCRIPTION OF FIGURES

In order to more clearly illustrate the technical solutions in the embodiments of the present disclosure, the figures used in the description of the embodiments will be briefly described below. It is obvious that the figures in the following description are only some embodiments of the present disclosure. Other figures can also be obtained from those skilled in the art based on these figures without inventive steps.

FIG. 1 shows a schematic structural diagram of a cover window structure of the present disclosure.

FIG. 2 shows a schematic structural diagram of an OLED display device according to the present disclosure.

### DETAILED DESCRIPTION OF PREFERRED EMBODIMENTS

The following is a description of each embodiment with reference to additional figures to illustrate specific embodiments in which the present disclosure can be implemented. The directional terms mentioned in the present disclosure, such as up, down, front, back, left, right, inside, outside, side, etc., are only directions referring to the figures. The names of the elements mentioned in the present disclosure, such as first, second, etc., are only used to distinguish different components, which can be better expressed. In the figure, similarly structured units are denoted by the same reference numerals.

The present disclosure is directed to the existing cover window structures and

OLED display devices, in that the material used in the existing cover window structures is too soft or too hard, which cannot effectively protect the OLED display panel, and further affects the performance of the OLED display device. The present disclosure can improve this technical problem.

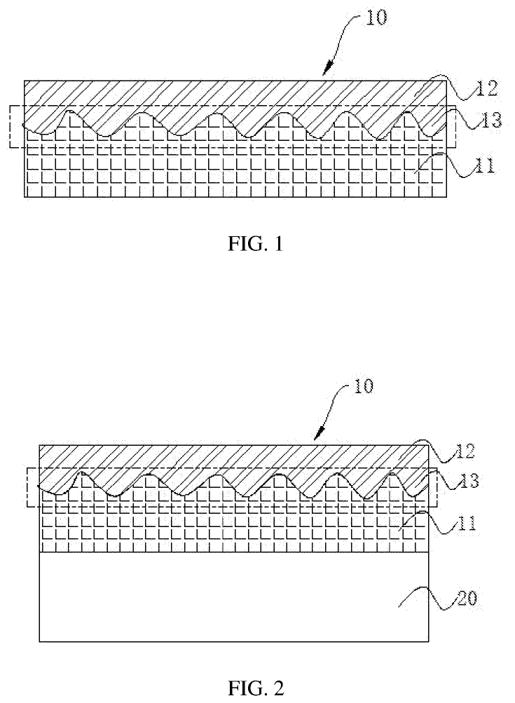

As shown in FIG. 1, FIG. 1 shows a schematic structural diagram of a cover window structure of the present disclosure. The cover window structure 10 includes a transparent substrate 11 and a hard coating layer 12 disposed on the transparent substrate 11;
wherein a region near a contact surface between the transparent substrate 11 and the hard coating layer 12 forms a molecular exchange layer 13 by a molecular exchange method, and a hardness of the molecular exchange layer 13 is greater than a hardness of the transparent substrate 11 and is less than a hardness of the hard coating layer 12. The cover window structure 10 can improve bending resistance of the cover window 10 while maintaining the hardness of the cover window 10 through a hard-medium-soft sandwich structure.

Preferably, a material of the transparent substrate 11 is selected from the group of a polyimide, a polyethylene terephthalate, a polyethylene naphthalate, and a polymethyl methacrylate. In this case, a thickness of the transparent substrate 11 ranges between 30 micrometers and 60 micrometers.

Specifically, the hard coating layer 12 disposed on the transparent substrate 11 can protect the transparent substrate 11 which is easily scratched and has a soft texture. Preferably, the hard coating layer 12 may be formed by a silica organic-inorganic composite ingredient. For example, the hard coating layer 12 may be mixed with an inorganic binder as a SiO2 particle having an acrylic-based modified surface and an acryl binder as an organic binder. Preferably, a thickness of the hard coating layer 12 ranges between 10 microns and 30 microns. Because the hard coating layer 12 is a combination of inorganic and organic materials, it needs to be coated with a certain thickness to maintain high hardness. However, because the hard coating layer 12 is a brittle material, the material is prone to explode and crack when it is pulled under external bending, surface stress is greater when the thickness is greater, and the risk of exploding and cracking is greater. Therefore, in order to solve this problem, a region near a contact surface between the transparent substrate 11 and the hard coating layer 12 forms a molecular exchange layer 13 by a molecular exchange method, and the molecular exchange layer 13 includes molecules of the transparent substrate 11 and the hard coating layer 12. Since a hardness of the material of the hard coating layer 12 is greater than a hardness of the material of the transparent substrate 11, a hardness of the molecular exchange layer 13 is between the hardness of the material of the hard coating layer 12 and the hardness of the material of the transparent substrate 11.

Preferably, the molecular exchange method is a high-temperature heating method or a coating process improvement method.

In one embodiment of the present disclosure, the molecular exchange method is a high-temperature heating method, and the specific steps are as follows:
first, performing a semiconductor manufacturing Run-to-Run (R2R) process to coat the hard coating layer 12 on the transparent substrate 11, and then heating a coil material in sections and multiple steps with the high temperature for preforming molecular exchange. A heating temperature of the high-temperature heating method is a higher one between a glass transition temperature (Tg1) of a material of the transparent substrate 11 and a glass transition temperature (Tg2) of a material of the hard coating layer 12. After sufficient molecular exchange, an area near the contact surface between the transparent substrate 11 and the hard coating layer 12 forms the molecular exchange layer 13, and finally the cover window structure 10 is manufactured.

In one embodiment of the present disclosure, the molecular exchange method is a high-temperature heating method, and the specific steps are as follows:
first, performing a semiconductor manufacturing Run-to-Run (R2R) process to coat the hard coating layer 12 on the transparent substrate 11, and then heating a coil material in sections and multiple steps with the high temperature for preforming molecular exchange. A heating temperature of the high-temperature heating method is between a glass transition temperature (Tg1) of a material of the transparent substrate 11 and a glass transition temperature (Tg2) of a material of the hard coating layer 12. After sufficient molecular exchange, an area near the contact surface between the transparent substrate 11 and the hard coating layer 12 forms the molecular exchange layer 13, and finally the cover window structure 10 is manufactured.

In one embodiment of the present disclosure, the molecular exchange method is a coating process improvement method, the specific steps are as follows:
first, coating the transparent substrate 11 into a film, and coating the hard coating layer 12 when the transparent substrate 11 is not completely cured. At this time, there is molecular exchange between a contact surface of the transparent substrate 11 and the hard coating layer 12. Finally, forming the cover window structure 10 having a hard-medium-soft structure.

By performing molecular exchange in a contact surface within a certain thickness range of the transparent substrate 11 and the hard coating layer 12, the cover window structure 10 having a hard-medium-soft structure of the present disclosure is formed. While maintaining the hardness, the problem of exploding and cracking of the hard coating layer 12 during bending is relieved, and the bending resistance of the cover window structure 10 is improved.

As shown in FIG. 2, FIG. 2 shows a schematic structural diagram of an OLED display device according to the present disclosure. The OLED display device includes an OLED display panel 20 and a cover window structure 10 disposed on the display panel 20. The cover window structure is disposed on the front side, ie, the display side of the OLED display panel 20 to protect the OLED display panel 20.

The cover window structure 10 includes the transparent substrate 11 and the hard coating layer 12 disposed on the transparent substrate 11, wherein a region near a contact surface between the transparent substrate 11 and the hard coating layer 12 forms a molecular exchange layer 13 by a molecular exchange method, and the hardness of the molecular exchange layer 13 is greater than the hardness of the transparent substrate 11 and is less than the hardness of the hard coating layer 12.

The OLED display device of the present disclosure forms the cover window structure 10 by performing molecular exchange on a region near a contact surface between the transparent substrate 11 and the hard coating layer 12 inside the cover window structure 10, forming the cover window structure 10 having a hard-medium-soft structure. At the same time, while maintaining the hardness, the problem of exploding and cracking of the hard coating layer 12 during bending is relieved, and the bending resistance of the cover window structure 10 is improved, further improving the bending resistance of the OLED display device.

The beneficial effect of the present disclosure is that the cover window structure and the OLED display device provided by the present disclosure design the cover window structure as a hard-medium-soft sandwich structure, effectively improving the bending resistance of the cover window structure, and further improving the performance of OLED display devices.

The above description only the preferred embodiments of the present disclosure. It should be noted that for those of ordinary skill in the art without departing from the principles of the present disclosure, several improvements and adjustments can be made, and these improvements and adjustments should also be considered in the protection scope of the present disclosure.

1. A cover window structure, including a transparent substrate and a hard coating layer disposed on the transparent substrate;
wherein a region near a contact surface between the transparent substrate and the hard coating layer forms a molecular exchange layer by a molecular exchange method, and a hardness of the molecular exchange layer is greater than a hardness of the transparent substrate and is less than a hardness of the hard coating layer.

2. The cover window structure as claimed in claim 1, wherein the molecular exchange method is a high-temperature heating method.

3. The cover window structure as claimed in claim 2, wherein a heating temperature of the high-temperature heating method is a higher one between a glass transition temperature of a material of the transparent substrate and a glass transition temperature of a material of the hard coating layer.

4. The cover window structure as claimed in claim 2, wherein a heating temperature of the high-temperature heating method is between a glass transition temperature of a material of the transparent substrate and a glass transition temperature of a material of the hard coating layer.

5. The cover window structure as claimed in claim 1, wherein the molecular exchange method further includes a coating process improvement method.

6. The cover window structure as claimed in claim 1, wherein a material of the transparent substrate is selected from the group of a polyimide, a polyethylene terephthalate, a polyethylene naphthalate, and a polymethylmethacrylate.

7. The cover window structure as claimed in claim 1, wherein a thickness of the transparent substrate ranges between 30 microns and 60 microns.

8. The cover window structure as claimed in claim 1, wherein a thickness of the hard coating layer ranges between 10 microns and 30 microns.

9. An organic light-emitting diode (OLED) display device, comprising an OLED display panel and a cover window structure disposed on the display panel, wherein the cover window structure includes a transparent substrate and a hard coating layer disposed on the transparent substrate, a region near a contact surface between the transparent substrate and the hard coating layer forms a molecular exchange layer by a molecular exchange method, and a hardness of the molecular exchange layer is greater than a hardness of the transparent substrate and is less than a hardness of the hard coating layer.

10. The OLED display device as claimed in claim 9, wherein the molecular exchange method is a high-temperature heating method or a coating process improvement method.
